(19) United States
(12) Patent Application Publication
(10) Pub. No.: US 2024/0431174 A1
(43) Pub. Date: Dec. 26, 2024

(54) DISPLAY DEVICE

(71) Applicant: Shanghai Tianma Micro-Electronics Co., Ltd., Shanghai (CN)

(72) Inventors: Hitoshi YOSHIDA, Kawasaki (JP); Noriyuki ITOU, Kawasaki (JP); Futoshi NAKANISHI, Kawasaki (JP); Akira BANJOUYA, Kawasaki (JP); Akira SUZUKI, Kawasaki (JP); Shingo ASAKA, Kawasaki (JP); Koetsu ISHIKAWA, Kawasaki (JP)

(73) Assignee: Shanghai Tianma Micro-Electronics Co., Ltd., Shanghai (CN)

(21) Appl. No.: 18/743,599

(22) Filed: Jun. 14, 2024

(30) Foreign Application Priority Data
Jun. 23, 2023 (JP) 2023-103472
Feb. 26, 2024 (JP) 2024-026834

(51) Int. Cl. H10K 59/38; H10K 59/131; H10K 59/80

(52) U.S. Cl. CPC H10K 59/38; H10K 59/131; H10K 59/8792

(57) ABSTRACT

A display device includes a display including a display panel in which a plurality of pixels is arranged, and a decorative member disposed on one of a display surface side and a rear surface side of the display panel; and a color changer that emits illumination light from the rear surface side of the display on the display panel and the decorative member. Each pixel of the plurality of pixels includes a pixel display region that emits display light and a transmission region that transmits light. The color changer emits, in accordance with a color of a design of the decorative member to be presented to an observer, illumination light of a predetermined color on the display panel and the decorative member.

### CROSS-REFERENCE TO RELATED APPLICATIONS

This application claims the benefit of Japanese Patent Application No. 2023-103472, filed on Jun. 23, 2023, and Japanese Patent Application No. 2024-26834, filed on Feb. 26, 2024, of which the entirety of the disclosures is incorporated by reference herein.

### FIELD OF THE INVENTION

The present disclosure relates generally to a display device.

### BACKGROUND OF THE INVENTION

In the related art, liquid crystal display devices are known in which a light-transmitting decorative member is disposed on a display surface side of a display panel to improve design. For example, Unexamined Japanese Patent Application Publication No. 2018-10029 describes a display device including a display device front surface protection panel and a display panel. The display device front surface protection panel includes, on one surface of a light-transmitting substrate, a first color adjusting layer that adjusts a color of the light-transmitting substrate, a first decorative layer formed from a resin that includes a white pigment, and a second color adjusting layer that adjusts a color of the first decorative layer. The first color adjusting layer is provided in a display region and a non-transparent region of the light-transmitting substrate. The second color adjusting layer is provided on the first color adjusting layer provided in the non-transparent region of the light-transmitting substrate. The first decorative layer is provided on the second color adjusting layer.

In Unexamined Japanese Patent Application Publication No. 2018-10029, the color of the display region is adjusted by the first color adjusting layer. The color of the non-transparent region is adjusted by the first color adjusting layer, the second color adjusting layer, and the first decorative layer. Due to this, both the display region and the non-transparent region can be adjusted to desired colors.

In the display device of Unexamined Japanese Patent Application Publication No. 2018-10029, the display device front surface protective panel must be replaced in order to change the color of the display region and the color of the non-transparent region of the manufactured display device. Additionally, while the display device of Unexamined Japanese Patent Application Publication No. 2018-10029 is in use, it is not possible to change the color of the display region and the color of the non-transparent region.

### SUMMARY OF THE INVENTION

A display device of the present disclosure includes:
a display including a display panel in which a plurality of pixels is arranged, and a decorative member disposed on one of a display surface side and a rear surface side of the display panel; and
a color changer that emits illumination light from the rear surface side of the display on the display panel and the decorative member, wherein
each pixel of the plurality of pixels includes a pixel display region that emits display light, and a transmission region that transmits light, and
the color changer emits, in accordance with a color of a design of the decorative member to be presented to an observer, the illumination light of a predetermined color on the display panel and the decorative member.

It is to be understood that both the foregoing general description and the following detailed description are exemplary and explanatory and are not restrictive of this disclosure.

### BRIEF DESCRIPTION OF DRAWINGS

A more complete understanding of this application can be obtained when the following detailed description is considered in conjunction with the following drawings, in which:

FIG. 1 is a schematic drawing illustrating a side surface of a display device according to Embodiment 1;

FIG. 2 is a plan view illustrating a display panel according to Embodiment 1;

FIG. 3 is a plan view illustrating a pixel according to Embodiment 1;

FIG. 4 is a cross-sectional view of the pixel illustrated in FIG. 3, taken along line A-A;

FIG. 5 is a cross-sectional view of the pixel illustrated in FIG. 3, taken along line B-B;

FIG. 6 is a plan view illustrating a decorative member according to Embodiment 1;

FIG. 7 is a cross-sectional view illustrating the decorative member depicted in FIG. 6, taken along line C-C;

FIG. 8 is a plan view illustrating a color changer according to Embodiment 1;

FIG. 9 is a schematic drawing illustrating a cross section of the color changer according to Embodiment 1;

FIG. 10 is a schematic drawing illustrating pixels of the color changer according to Embodiment 1;

FIG. 11 is a block diagram illustrating the configuration of a controller according to Embodiment 1;

FIG. 12 is a schematic drawing illustrating side surfaces of a display panel, a decorative member, and a color changer according to Embodiment 2;

FIG. 13 is a plan view illustrating a region that does not display a display element, according to Embodiment 2;

FIG. 14 is a schematic drawing illustrating a side surface of a display device according to Embodiment 3;

FIG. 15 is a plan view illustrating a display panel according to Embodiment 4;

FIG. 16 is a schematic drawing illustrating pixels according to Embodiment 4;

FIG. 17 is a drawing illustrating a pixel circuit according to Embodiment 4;

FIG. 18 is a cross-sectional view illustrating an organic light-emitting diode according to Embodiment 4;

FIG. 19 is a plan view illustrating an example of illumination light according to Embodiment 5;

FIG. 20 is a plan view illustrating an example of displaying of a display device according to Embodiment 5;

FIG. 21 is a schematic drawing illustrating signal wires and connections of pixel electrodes according to Embodiment 6;

FIG. 22 is a cross-sectional view illustrating a micro LED element according to a modified example;

FIG. 23 is a schematic drawing illustrating a pixel according to a modified example;

FIG. 24 is a cross-sectional view illustrating a light blocking layer according to a modified example;

FIG. 25 is a cross-sectional view illustrating a light blocking layer according to a modified example;

FIG. 26 is a schematic drawing illustrating a side surface of a display device according to a modified example.

### DETAILED DESCRIPTION OF THE INVENTION

Hereinafter, a display device according to various embodiments is described while referencing the drawings.

### Embodiment 1

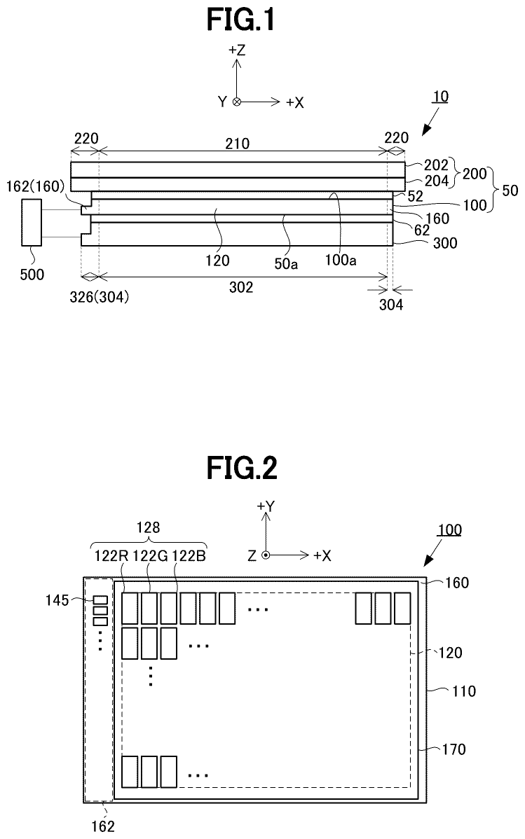

A display device 10 according to the present embodiment is described while referencing FIGS. 1 to 11. As illustrated in FIG. 1, the display device 10 includes a display 50, a color changer 300, and a controller 500. The display 50 includes a display panel 100 and a decorative member 200. The display panel 100 displays a display element. The decorative member 200 is a member that provides a design to an observer (user). The color changer 300 emits illumination light on the display panel 100 and the decorative member 200 from a rear surface side of the display 50. The controller 500 controls the display panel 100 and the color changer 300. In the present specification, the term “display element” refers to a character, a character string, an image, an icon, an operation button, a menu, or the like.

The display device 10 is provided on a dashboard of a vehicle, a piece of furniture, a home electronic device, or the like. Note that, in the present description, to facilitate comprehension, in the display device 10 of FIG. 1, the longitudinal right direction (the right direction on paper) is referred to as the “+X direction”, the up direction (the up direction on paper) is referred to as the “+Z direction”, and the direction perpendicular to the +X direction and the +Z direction (the depth direction on paper) is referred to as the “+Y direction.”

### Display

In one example, the display panel 100 of the display 50 is implemented as a micro light emitting diode (LED) display panel. As illustrated in FIG. 2, the display panel 100 includes a light-transmitting substrate 110, and a sealer 170.

The light-transmitting substrate 110 of the display panel 100 includes a displayable region 120, and a frame region 160 surrounding the displayable region 120. The displayable region 120 is a region in which the display element is displayable. A pixel 122R that emits red light, a pixel 122G that emits green light, and a pixel 122B that emits blue light are arranged in the displayable region 120. The frame region 160 is a region in which the display element cannot be displayed. In the following, the pixels 122R, 122B, and 122G may be referred to collectively as “pixels 122.”

The pixel 122R, the pixel 122B, and the pixel 122G are arranged in the +X direction to form one main pixel 128. The main pixel 128 is arranged in a matrix. The pixel 122R, the pixel 122B, and the pixel 122G are also respectively arranged in single rows in the Y direction.

As illustrated in FIG. 3, each of the pixels 122 includes a transmission region 124 and a pixel display region 126. The transmission region 124 transmits light. The pixel display region 126 is a region that emits display light for displaying the display element. In the present embodiment, a micro LED element 130 is disposed in the pixel display region 126. Specifically, a micro LED element 130R that emits red display light is disposed in the pixel display region 126 of the pixel 122R. A micro LED element 130G that emits green display light is disposed in the pixel display region 126 of the pixel 122G. A micro LED element 130B that emits blue display light is disposed in the pixel display region 126 of the pixel 122B. Note that, the sealer 170 and a first insulation layer 146, described later, and the like are omitted from FIG. 3. Also, note that the micro LED element 130R, the micro LED element 130G, and the micro LED element 130B correspond to light emitting elements.

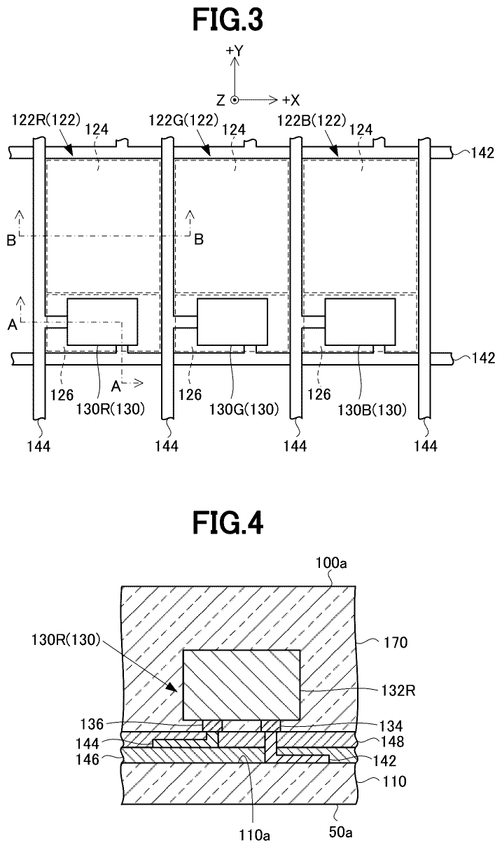

As illustrated in FIG. 4, the micro LED element 130R includes a micro LED chip 132R that emits red light, a cathode electrode 134, and an anode electrode 136. The micro LED element 130G includes a micro LED chip (not illustrated) that emits green light, a cathode electrode 134, and an anode electrode 136. The micro LED element 130B includes a micro LED chip (not illustrated) that emits blue light, a cathode electrode 134, and an anode electrode 136. The cathode electrode 134 and the anode electrode 136 are respectively connected to a first wiring 142 and a second wiring 144, described later.

Emission light intensity (intensity of the display light) of the micro LED element 130R, the micro LED element 130G, and the micro LED element 130B are independently adjusted by power supplied from a non-illustrated driver integrated circuit (IC) via the first wiring 142 and the second wiring 144. As a result, the display element is displayed on the display panel 100.

As illustrated in FIGS. 3 and 4, the light-transmitting substrate 110 includes a plurality of the first wiring 142 and a plurality of the second wiring 144 on the main surface 110a on which the micro LED element 130 is mounted. The first wiring 142 and the second wiring 144 supply power to the micro LED elements 130R, 130G, and 130B. The first wiring 142 and the second wiring 144 are formed from a metal such as indium tin oxide (ITO), copper (Cu), or the like. The first wiring 142 and the second wiring 144 are connected to a terminal 145, described later, via a wiring (not illustrated) disposed in the frame region 160.

The first wiring 142 is formed on the main surface 110a of the light-transmitting substrate 110. The first wiring 142 extends in the X direction and is arranged in the Y direction. The first wiring 142 is covered by a first insulation layer 146 and a second insulation layer 148. The first wiring 142 is connected to the cathode electrode 134 of the micro LED element 130 via a through-hole of the first insulation layer 146 and the second insulation layer 148.

The second wiring 144 is formed on the first insulation layer 146. The second wiring 144 extends in the Y direction and is arranged in the X direction. The second wiring 144 is covered by the second insulation layer 148. The second wiring 144 is connected to the anode electrode 136 of the micro LED element 130 via a through-hole of the second insulation layer 148.

The first insulation layer 146 and the second insulation layer 148 are formed from silicon nitride (SiNx), silicon oxide (SiOx), or the like. As illustrated in FIG. 5, the first insulation layer 146 and the second insulation layer 148 are not formed in the transmission region 124.

As illustrated in FIG. 2, the terminal 145 is provided in a terminal region 162 positioned on the −X-side end of the light-transmitting substrate 110. Note that the terminal region 162 is a portion of the frame region 160.

The terminal 145 is a terminal for connecting the first wiring 142 and the second wiring 144 to outside the display panel 100. The phrase “outside the display panel 100” refers to a device, a member, a drive circuit, or the like other than the display panel 100. In the present embodiment, the terminal 145 is connected to a driver IC via a flexible printed circuit (FPC).

The sealer 170 of the display panel 100 is provided on the main surface 110a of the light-transmitting substrate 110. The sealer 170 covers the micro LED element 130, the first wiring 142, the second wiring 144, the second insulation layer 148, and the like, and protects these components. In one example, the sealer 170 is formed from a light-transmitting resin.

The decorative member 200 of the display 50 is a light-transmitting member that provides a design to the observer. As illustrated in FIG. 1, the decorative member 200 is provided on a display surface 100a side (the +Z side) of the display panel 100 via a light-transmitting adhesive layer 52. In the present embodiment, the decorative member 200 transparently displays the display element to be displayed on the display panel 100.

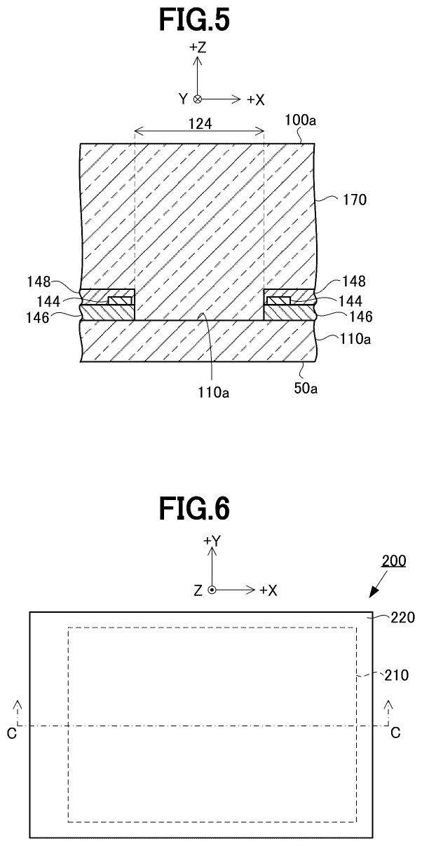

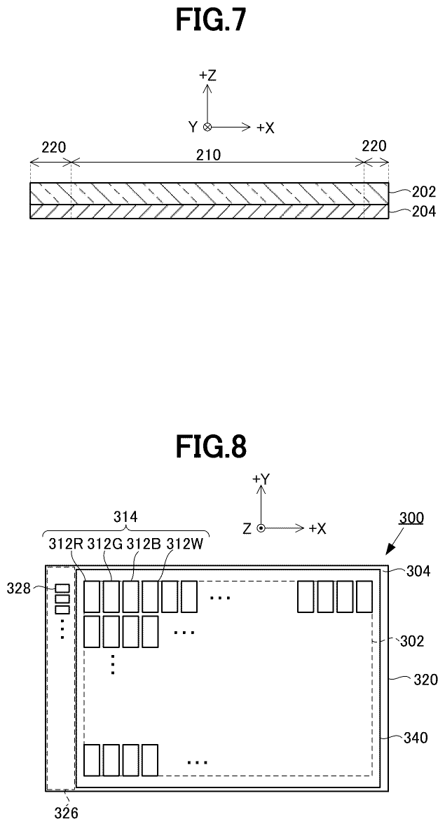

As illustrated in FIGS. 6 and 7, the decorative member 200 includes, in a flat plate shape, a display region 210, and a non-display region 220 surrounding the display region 210. As illustrated in FIG. 1, the display region 210 overlaps the displayable region 120 of the display panel 100, and transparently displays the display element to be displayed on the display panel 100. The non-display region 220 overlaps the frame region 160 of the display panel 100.

As illustrated in FIG. 7, the decorative member 200 includes a light-transmitting film 202 and a decorative layer 204. In one example, the light-transmitting film 202 is formed from a light-transmitting synthetic resin. The decorative layer 204 is a layer that provides a design to the observer. In one example, the decorative layer 204 is formed by printing, in a desired color, a desired pattern such as a wood grain look, a marble look, or a geometric pattern on the light-transmitting film 202. In the following, an example is described in which the color of the design of the decorative member 200 (the decorative layer 204) is dark brown.

### Color Changer

The color changer 300 of the display device 10 emits illumination light of a predetermined color on the display panel 100 and the decorative member 200 (the display 50) in accordance with the color of the design of the decorative member 200 (the decorative layer 204) to be presented to the observer. The color changer 300 can change the color of the design of the decorative member 200 to be presented to the observer by changing the color (wavelength region) of the illumination light emitted on the display panel 100 and the decorative member 200 from a rear surface 50a side (the −Z side) of the display 50.

In the present embodiment, the color changer 300 is implemented as an electrophoresis display panel that includes a color filter and is driven by thin film transistors (TFT). As illustrated in FIG. 1, the color changer 300 is disposed on the rear surface 50a side (the −Z side) of the display 50. The color changer 300 is affixed to the display panel 100 via a light-transmitting adhesive layer 62. The color changer 300 reflects external light that enters through the light-transmitting decorative member 200 and the transmission region 124 of each of the pixels 122 of the display panel 100. The color changer 300 changes the color of the light reflected toward the display panel 100 and the decorative member 200 to change the color of the illumination light emitted on the display panel 100 and the decorative member 200. Here, the term “external light” refers to light, including sunlight and illumination light, that enters the display device 10 from around the display device 10.

As illustrated in FIG. 8, the color changer 300 includes an emission region 302, and a frame region 304 surrounding the emission region 302. The emission region 302 is a region that reflects external light toward the display panel 100 and the decorative member 200. A pixel 312R that reflects red light, a pixel 312G that reflects green light, a pixel 312B that reflects blue light, and a pixel 312W that reflects white light are arranged in the emission region 302. The frame region 304 is a region that cannot reflect the external light. As illustrated in FIG. 1, the emission region 302 overlaps the displayable region 120 of the display panel 100 and the display region 210 of the decorative member 200, and the frame region 304 overlaps the frame region 160 of the display panel 100 and the non-display region 220 of the decorative member 200. In the following, the pixels 312R, 312G, 312B, and 312W may be referred to collectively as “pixels 312.”

As illustrated in FIG. 8, the pixel 312R, the pixel 312B, the pixel 312G, and the pixel 312W are arranged in the +X direction to form one main pixel 314. The main pixel 314 is arranged in a matrix. Additionally, the pixel 312R, the pixel 312B, the pixel 312G, and the pixel 312W are respectively arranged in single rows in the Y direction.

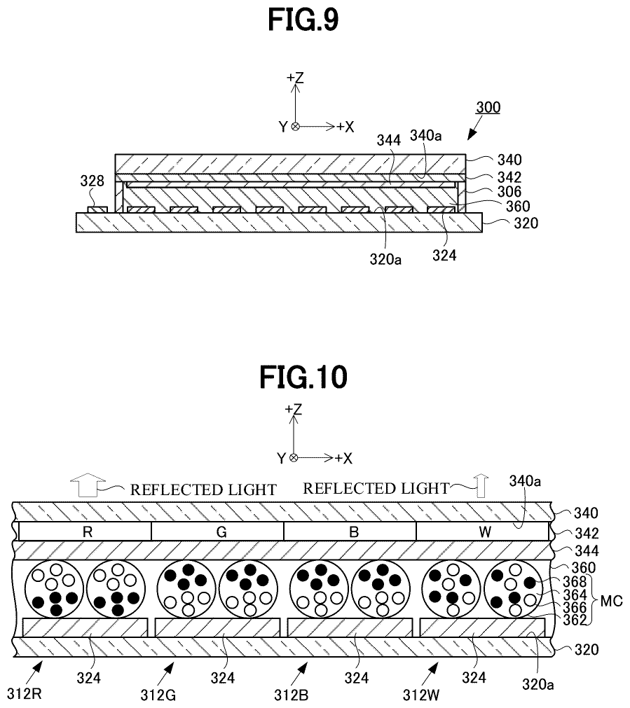

As illustrated in FIG. 9, the color changer 300 includes a first substrate 320, a second substrate 340, and an electrophoretic layer 360. The first substrate 320 and the second substrate 340 sandwich the electrophoretic layer 360.

In one example, the first substrate 320 of the color changer 300 is implemented as a glass substrate. A pixel electrode 324 is provided on a main surface 320a of the electrophoretic layer 360 side of the first substrate 320. Furthermore, TFTs, a plurality of signal wires, a plurality of scanning wires, and the like (all not illustrated in the drawings) for selecting the pixels 312 are provided on the main surface 320a of the first substrate 320. The signal wires supply, via the TFTs, voltage to the pixel electrode 324 that applies voltage to the electrophoretic layer 360. The scanning wires supply voltage that causes the TFTs to operate. The pixels 312 are surrounded by the signal wires and the scanning wires, and the TFTs are provided at intersections between the scanning wires and the signal wires.

As with the light-transmitting substrate 110 of the display panel 100, a terminal region 326 is provided at the −X-side end of the first substrate 320. A plurality of terminals 328 is disposed in the terminal region 326. The terminals 328 connect the signal wires, the scanning wires, and a counter-electrode 344 of the second substrate 340, described later, to outside. In the present embodiment, the terminals 328 are connected to non-illustrated driver ICs via FPCs. The terminal region 326 is a portion of the frame region 304.

The second substrate 340 of the color changer 300 opposes the first substrate 320. The second substrate 340 is affixed to the first substrate 320 by a sealing material 306. In one example, the second substrate 340 is implemented as a glass substrate. A color filter layer 342 is provided on a main surface 340a of the electrophoretic layer 360 side of the second substrate 340. In one example, the color filter layer 342 is implemented as a stripe-like color filter. A red color filter R, a green color filter G, a blue color filter B, and a white color filter W of the color filter layer 342 respectively correspond to the pixel 312R, the pixel 312B, the pixel 312G, and the pixel 312W. Additionally, a counter-electrode 344 is provided on the main surface 340a of the second substrate 340.

As illustrated in FIG. 10, the electrophoretic layer 360 of the color changer 300 includes a plurality of microcapsules MC. Each of the microcapsules MC includes, in a shell 362, a dispersion medium 364, white particles 366, and black particles 368. The shell 362 is formed from a light-transmitting resin (for example, acrylic resin). The dispersion medium 364 is an alcohol solvent, a silicon solvent, or the like. The white particles 366 are white microparticles that are positively or negatively charged and, in one example, are formed from titanium oxide (TiO₂). The black particles 368 are black microparticles that are charged the opposite of the white particles 366 and, in one example, are formed from carbon black.

The white particles 366 and the black particles 368 of the microcapsules MC move to the first substrate 320 side or the second substrate 340 side in accordance with voltage applied between the pixel electrode 324 of the first substrate 320 and the counter-electrode 344 of the second substrate 340. Accordingly, the color of the light reflected toward the display panel 100 and the decorative member 200 can be changed by controlling the voltage applied between the pixel electrode 324 and the counter-electrode 344. For example, in FIG. 10, the white particles 366 of the pixel 312R move to the second substrate 340 side, the black particles 368 of the pixel 312G and the pixel 312B move to the second substrate 340 side, and the white particles 366 and the black particles 368 of the pixel 312W are uniformly dispersed. In this case, red light is reflected by the pixel 312R, and white light is reflected by the pixel 312W. Accordingly, red illumination light is emitted on the display panel 100 and the decorative member 200 from the color changer 300.

When the white particles 366 of the pixel 312R and the pixel 312G move to the second substrate 340 side, and the black particles 368 of the pixel 312B move to the second substrate 340 side, yellow illumination light is emitted on the display panel 100 and the decorative member 200 from the color changer 300. When the black particles 368 of the pixel 312R, the pixel 312G, the pixel 312B, and the pixel 312W move to the second substrate 340 side, the external light is not reflected by the color changer 300, and the illumination light is not emitted on the display panel 100 and the decorative member 200 from the color changer 300.

The illumination light emitted on the display panel 100 and the decorative member 200 from the color changer 300 enters the decorative member 200 through the transmission region 124 of each of the pixels 122 of the display panel 100. In the present embodiment, the color of the design of the decorative member 200 is dark brown and, as such, when red illumination light is emitted, the observer recognizes the color of the design of the decorative member 200 as reddish brown. Accordingly, the color changer 300 emits red illumination light (illumination light of a predetermined color) when setting the color of the design of the decorative member 200 presented to the observer to reddish brown. Additionally, it is sufficient that the color changer 300 emits yellow illumination light when setting the color of the design of the decorative member 200 presented to the observer to yellowish brown.

As described above, with the display device 10, the color changer 300 can easily change the color of the design presented to the observer by emitting illumination light of a predetermined color on the display panel 100 and the decorative member 200 in accordance with the color of the design of the decorative member 200 to be presented to the observer. Note that, when the color changer 300 does not emit illumination light on the decorative member 200, the observer recognizes the color of the design of the decorative member 200 as dark brown.

### Controller

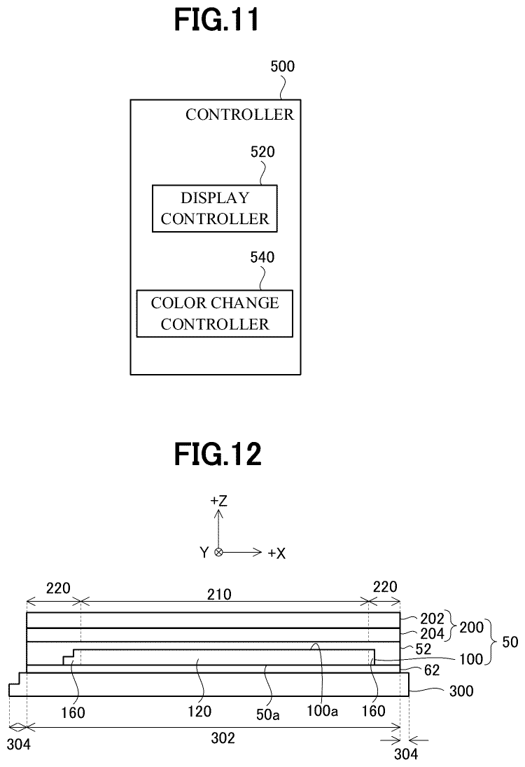

The controller 500 of the display device 10 controls the display panel 100 and the color changer 300. As illustrated in FIG. 11, the controller 500 includes a display controller 520, and a color change controller 540.

The display controller 520 of the controller 500 controls displaying of the display panel 100 via a driver IC. The display controller 520 generates a display signal on the basis of data expressing the display element input from outside, and sends the display signal to the driver IC. The display panel 100 displays the display element on the basis of a signal (voltage) from the driver IC. The display controller 520 may set the color through the decorative member 200 of the display element (that is, the color of the display element presented to the observer) to a complementary color of the color of the design of the decorative member 200 to be presented to the observer. For example, when setting the color of the design of the decorative member 200 to be presented to the observer to reddish brown (for example, in RGB values, R: 102, G: 21, B: 24), the display controller 520 may set the color through the decorative member 200 of the display element to dark-greyish-blue-green (for example, in RGB values, R: 21, G: 102, B: 99). As a result, the recognizability of the display element can be enhanced.

The color change controller 540 of the controller 500 controls, on the basis of a command from outside and via the driver IC, the illumination light (amount of light, color, and the like) that the color changer 300 emits on the display panel 100 and the decorative member 200 (the display 50). For example, when setting the color of the design of the decorative member 200 to be presented to the observer to dark brown, the color change controller 540 controls, via the driver IC, the voltage applied between the pixel electrode 324 and the counter-electrode 344 of the color changer 300, and causes the black particles 368 of the pixel 312R, the pixel 312G, the pixel 312B, and the pixel 312W to move to the second substrate 340 side. As a result, the color changer 300 does not emit the illumination light on the decorative member 200 and, as such, the observer recognizes the color of the design of the decorative member 200 as dark brown.

Additionally, when setting the color of the design of the decorative member 200 to be presented to the observer to reddish brown, the color change controller 540 controls the voltage applied between the pixel electrode 324 and the counter-electrode 344 of the color changer 300, and causes the color changer 300 to emit red illumination light.

The controller 500 is configured from a central processing unit (CPU), a memory, and the like. In one example, the CPU executes programs stored in the memory to realize the functions of the controller 500.

As described above, the color changer 300 emits illumination light of a predetermined color on the display panel 100 and the decorative member 200 in accordance with the color of the design of the decorative member 200 to be presented to the observer and, as such, the display device 10 can easily change the color of the design to be presented to the observer. Additionally, the controller 500 can enhance the recognizability of the display element of the display device 10 by setting the color through the decorative member 200 of the display element to a complementary color of the color of the design of the decorative member 200 to be presented to the observer.

### Embodiment 2

A configuration is possible in which the color changer 300 emits light on the non-display region 220 of the decorative member 200. As with the display device 10 of Embodiment 1, a display device 10 of the present embodiment includes a display panel 100, a decorative member 200, a color changer 300, and a controller 500.

In the present embodiment, as illustrated in FIG. 12, the decorative member 200 and the color changer 300 have outer shapes that are larger than an outer shape of the display panel 100. Additionally, the emission region 302 of the color changer 300 overlaps the display region 210 and the non-display region 220 of the decorative member 200. Due to this configuration, the color changer 300 can emit illumination light on the display region 210 and the non-display region 220 of the decorative member 200. The other configurations of the display panel 100, the decorative member 200, the color changer 300, and the controller 500 of the present embodiment are the same as in Embodiment 1.

A configuration is possible in which the color changer 300 of the present embodiment emits illumination light of different colors on the display region 210 of the decorative member 200 and the non-display region 220 of the decorative member 200 on the basis of control by the color change controller 540 of the controller 500. Such a configuration makes it possible to increase the variations of the design to be presented to the observer.

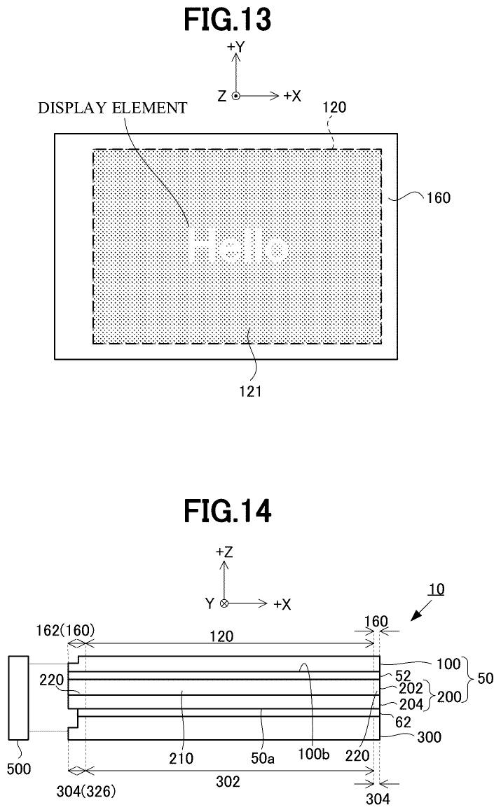

A configuration is possible in which the color changer 300 of the present embodiment changes, by the control of the color change controller 540 of the controller 500, an amount of the illumination light emitted on the non-display region 220 of the decorative member 200 in accordance with a brightness through the decorative member 200 of a region 121 (see FIG. 13), of the displayable region 120 of the display panel, not displaying the display element. In one example, the color change controller 540 of the controller 500 controls the amount of the illumination light emitted on the non-display region 220 of the decorative member 200 to an amount at which the brightness through the decorative member 200 of the region 121 not displaying the display element and the brightness of the non-display region 220 of the decorative member 200 match. Such a configuration makes it possible to make a boundary between the displayable region 120 and the frame region 160 of the display panel 100 less visible through the decorative member 200. Note that, in FIG. 13, to facilitate comprehension, the region 121 not displaying the display element is illustrated as hatching.

### Embodiment 3

In Embodiment 1, the decorative member 200 is provided on the display surface 100a side (the +Z side) of the display panel 100. However, a configuration is possible in which the decorative member 200 is provided on the rear surface 100b side of the display panel 100.

As with the display device 10 of Embodiment 1, a display device 10 of the present embodiment includes a display panel 100, a decorative member 200, a color changer 300, and a controller 500. In the present embodiment, as illustrated in FIG. 14, the decorative member 200 is provided on a rear surface 100b side (the −Z side) of the display panel 100 via a light-transmitting adhesive layer 52. The other configurations of the display panel 100, the decorative member 200, the color changer 300, and the controller 500 of the present embodiment are the same as in Embodiment 1.

In the present embodiment, the illumination light emitted on the display panel 100 and the decorative member 200 from the color changer 300 passes through the light-transmitting decorative member 200, then passes through the transmission region 124 of each of the pixels 122 of the display panel 100, and exits from the display panel 100 (the display 50). That is, the display panel 100 of the present embodiment transparently displays the design of the decorative member 200.

As in Embodiment 1, in the present embodiment as well, the color changer 300 emits illumination light of a predetermined color on the display panel 100 and the decorative member 200 in accordance with the color of the design of the decorative member 200 to be presented to the observer and, thereby, the display device 10 can easily change the color of the design to be presented to the observer. Furthermore, the display panel 100 is positioned more to the observer side (the +Z side) than the decorative member 200 and, as such, the display device 10 of the present embodiment can more clearly display the display element.

### Embodiment 4

In Embodiments 1 to 3, the micro LED elements 130R, 130G, and 130B are disposed as light emitting elements in the pixel display region 126 of each of the pixels 122 of the display panel 100. However, a configuration is possible in which other light emitting elements are disposed in the pixel display region 126.

As with the display device 10 of Embodiment 1, a display device 10 of the present embodiment includes a display panel 100, a decorative member 200, a color changer 300, and a controller 500. The display panel 100 of the present embodiment is implemented as an organic light emitting diode (OLED) display panel that is driven by TFTs. The configurations of the decorative member 200, the color changer 300, and the controller 500 in the present embodiment are the same as in Embodiment 1 and, as such, the display panel 100 of the present embodiment is described.

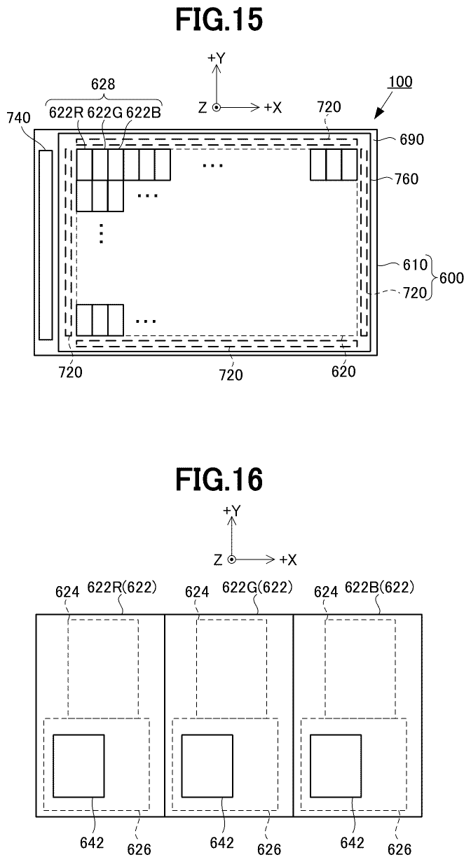

Firstly, the overall configuration of the display panel 100 of the present embodiment is described. As illustrated in FIG. 15, the display panel 100 of the present embodiment includes a TFT substrate 600, a driver IC 740, and a sealing substrate 760. The TFT substrate 600 includes a light transmitting substrate 610 and a driver circuit 720.

The light transmitting substrate 610 of the TFT substrate 600 includes a displayable region 620 and a frame region 690 surrounding the displayable region 620. The displayable region 620 is a region capable of displaying the display element. The driver circuit 720 of the TFT substrate 600 is provided in the frame region 690 of the light transmitting substrate 610.

In one example, the light transmitting substrate 610 is implemented as a glass substrate. Pluralities of pixels 622R, 622B, 622G are arranged in the displayable region 620 of the light transmitting substrate 610. In the following, the pixels 622R, 622B, and 622G may be referred to collectively as “pixels 622.”

The pixel 622R, the pixel 622B, and the pixel 622G are arranged in the +X direction to form one main pixel 628. The main pixel 628 is arranged in a matrix. The pixel 622R, the pixel 622B, and the pixel 622G are also respectively arranged in single rows in the Y direction.

As illustrated in FIG. 16, as with the pixels 122 of Embodiment 1, each of the pixels 622 includes a transmission region 624 and a pixel display region 626. As with the transmission region 124 of Embodiment 1, the transmission region 624 is a region that transmits light. Nothing is formed on the transmission region 624 of the light transmitting substrate 610. The pixel display region 626 is a region that emits display light for displaying the display element.

An organic light emitting diode 642, a pixel circuit 640, described later, that controls light emission of the organic light emitting diode 642, and the like are provided in the pixel display region 626. The organic light emitting diode 642 of the pixel 622R emits red light. The organic light emitting diode 642 of the pixel 622G emits green light. The organic light emitting diode 642 of the pixel 622B emits blue light.

Returning to FIG. 15, the driver circuit 720 drives, via gate lines 631, 633, a data line (Vdata) 635, a power line (Vdd) 636, a reference voltage supply line (Vref) 637, and a cathode line 638, the pixel circuit 640 provided in the pixel display region 626 of each of the pixels 622. The gate lines 631, 633, the data line 635, the power line (Vdd) 636, and the like are formed on the light transmitting substrate 610.

A driver IC 740 is provided on the −X-side end (the frame region 690) of the light transmitting substrate 610. The driver IC 740 supplies power, timing signals, and the like to the driver circuit 720. The driver IC 740 is connected to the controller 500 via an FPC.

The sealing substrate 760 is a light transmitting substrate. The sealing substrate 760 is joined to the TFT substrate 600 by glass frit to seal the displayable region 620 of the TFT substrate 600. In one example, dry air is enclosed between the sealing substrate 760 and the TFT substrate 600.

Next the pixel circuit 640 and the organic light emitting diode 642 are described. The pixel circuit 640 is provided in the pixel display region 626 of each of the pixels 622, and controls the light emission of the organic light emitting diode 642. The pixel circuit 640 is connected to the driver circuit 720 via the gate lines 631, 633, the data line (Vdata) 635, the power line (Vdd) 636, the reference voltage supply line (Vref) 637, and the cathode line 638.

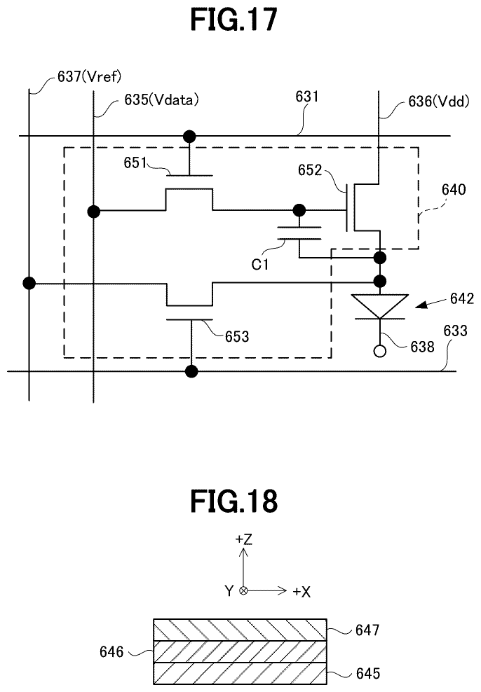

As illustrated in FIG. 17, the pixel circuit 640 includes a switching TFT 651, a driving TFT 652, a reset TFT 653, and a hold capacitor C1. The switching TFT 651, the driving TFT 652, and the reset TFT 653 function as thin film transistors that control the light emission of the organic light emitting diode 642. In the following, the switching TFT 651, the driving TFT 652, and the reset TFT 653 may be collectively referred to as “pixel TFTs 650.”

The switching TFT 651 is a transistor that selects the pixels 622. The gate of the switching TFT 651 is connected to the gate line 631, which functions as a scan line. The source of the switching TFT 651 is connected to the data line (Vdata) 635. The drain of the switching TFT 651 is connected to the gate of the driving TFT 652.

The driving TFT 652 is a transistor that drives the organic light emitting diode 642. The gate of the driving TFT 652 is connected to the drain of the switching TFT 651. The source of the driving TFT 652 is connected to the power line (Vdd) 636. The drain of the driving TFT 652 is connected to the anode of the organic light emitting diode 642. Note that the cathode of the organic light emitting diode 642 is connected to the cathode line 638.

The hold capacitor C1 is formed between the anode of the organic light emitting diode 642 and the gate of the driving TFT 652.

In one example, the reset TFT 653 is used to apply, to the anode of the organic light emitting diode 642, voltage less than or equal to a threshold voltage of the organic light emitting diode 642. By applying, to the anode of the organic light emitting diode 642, the voltage that is less than or equal to the threshold voltage of the organic light emitting diode 642, crosstalk, which is caused by leak current of the organic light emitting diode 642, can be suppressed. The gate of the reset TFT 653 is connected to the gate line 633. The source of the reset TFT 653 is connected to the reference voltage supply line (Vref) 637. The drain of the reset TFT 653 is connected to the anode of the organic light emitting diode 642.

Next, the operations of the pixel circuit 640 are described. Firstly, the driver circuit 720 outputs a selection signal to the gate line 631, thereby setting the switching TFT 651 to an open state. When the switching TFT 651 assumes the open state, the data voltage supplied via the data line (Vdata) 635 is held by the hold capacitor C1. Based on the voltage held by the hold capacitor C1, the open/close state of the driving TFT 652 changes, and current corresponding to the gradation of the organic light emitting diode 642 is supplied to the organic light emitting diode 642 from the power line (Vdd) 636.

Then, the organic light emitting diode 642 provided in the each of the pixels 622 emits light, and a color image is displayed in the displayable region 620. The reset TFT 653 is in an open state before a light emitting period in which the organic light emitting diode 642 emits light. When the reset TFT 653 assumes the open state, voltage less than or equal to the threshold voltage of the organic light emitting diode 642 is applied, from the reference voltage supply line (Vref) 637, to the anode of the organic light emitting diode 642. As a result, the potential of the anode of the organic light emitting diode 642 is reset.

As illustrated in FIG. 18, the organic light emitting diode 642 includes an anode electrode 645, a light emitting layer 646, and a cathode electrode 647. In one example, the anode electrode 645 is formed from three layers, namely ITO, aluminum alloy or silver alloy, and ITO. In one example, the light emitting layer 646 is formed from a hole injection layer, a hole transport layer, an organic light emitting layer, an electron transport layer, and an electron injection layer. The cathode electrode 647 is formed from lithium (Li), aluminum, magnesium (Mg), ytterbium (Yb), alloys thereof, or the like.

The anode electrode 645 is connected to the drain of the reset TFT 653. The cathode electrode 647 is connected to the cathode line 638.

In the present embodiment as well, each of the pixels 622 of the display panel 100 includes the transmission region 624 that transmits light. As such, the illumination light emitted on the display panel 100 and the decorative member 200 from the color changer 300 passes through the transmission region 624 of each of the pixels 622 of the display panel 100 and enters the decorative member 200. Accordingly, with the display device 10 of the present embodiment as well, the color changer 300 can easily change the color of the design presented to the observer by emitting illumination light of a predetermined color on the display panel 100 and the decorative member 200 in accordance with the color of the design of the decorative member 200 to be presented to the observer.

### Embodiment 5

In Embodiment 1, the color changer 300 emits monochromatic (red, yellow, and the like) illumination light on the display panel 100 and the decorative member 200. However, a configuration is possible in which the color changer 300 changes the color, brightness, or the like of the illumination light in accordance with a position within the displayable region 120 or a position within the decorative member 200 of the display panel 100.

As with the display device 10 of Embodiment 1, a display device 10 of the present embodiment includes a display panel 100, a decorative member 200, a color changer 300, and a controller 500. The configurations of the display panel 100, the decorative member 200, and the color changer 300 of the present embodiment are the same as in Embodiment 1 and, as such, the controller 500 and an example of the illumination light and the displaying of the present embodiment are described.

As with the controller 500 of Embodiment 1, the controller 500 of the present embodiment includes a display controller 520 and a color change controller 540. The configuration of the display controller 520 of the present embodiment is the same as the display controller 520 of Embodiment 1. As such, here, the color change controller 540 of the present embodiment is described.

The color change controller 540 of the present embodiment generates, on the basis of illumination data expressing a pattern of illumination light input from outside, a scanning signal, a gradation signal, and a control signal including a synchronization signal. In one example, the illumination data includes the pattern of the illumination light, a relationship between the gradation and the color of the pattern, and the like.

The color change controller 540 of the present embodiment sequentially outputs the scanning signal to each scanning wire of the color changer 300 on the basis of the control signal. Additionally, the color change controller 540 of the present embodiment converts the gradation signal to data voltage on the basis of the control signal, and outputs the data voltage to each signal wire of the color changer 300.

In the present embodiment, each electrophoretic layer 360 (each of the microcapsules MC) of the pixels 312 of the color changer 300 is driven by the potential difference between the data voltage applied to the pixel electrode 324 and the voltage of the counter-electrode 344. Due to this, the color changer 300 of the present embodiment can change, in accordance with the illumination data, the pattern of the illumination light reflected toward the display panel 100 and the decorative member 200, the color and gradation of the pattern, and the like.

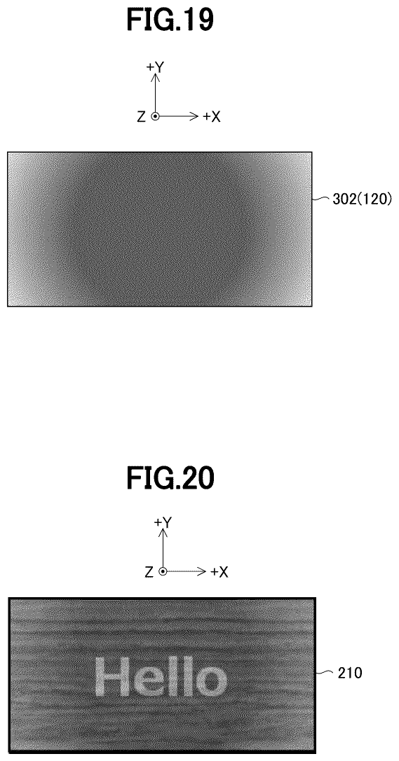

For example, as illustrated in FIG. 19, the color changer 300 of the present embodiment can emit, toward the display panel 100 and the decorative member 200, illumination light for which the color gradually lightens from the center toward the periphery of the displayable region 120 (the emission region 302 of the color changer 300) of the display panel 100 (that is, illumination light for which the brightness gradually decreases from the center toward the periphery of the displayable region 120 of the display panel 100). As a result, as illustrated in FIG. 20, the display device 10 displays an image in which the background color of the display element and the background color of the display element periphery are dark and the background color of the display region 210 periphery is light. Since the background color of the display element and the background color of the display element periphery are dark and the background color of the display region 210 periphery is light, the display device 10 can make the display element easier for the observer to see. Additionally, the display device 10 can impart a feeling of luxury to the displaying.

### Embodiment 6

In Embodiment 1, the color changer 300 is active matrix driven by the TFTs. However, a configuration is possible in which the color changer 300 is not active matrix driven.

As with the display device 10 of Embodiment 1, a display device 10 of the present embodiment includes a display panel 100, a decorative member 200, a color changer 300, and a controller 500. With the exception of the configurations of signal wires 329R, 329G, 329B, and 329W and the pixel electrode 324 of the color changer 300, and the color change controller 540 of the controller 500, the configuration of a display device 10 of the present embodiment is the same as the configuration of the display device 10 of Embodiment 1. As such, here, the signal wires 329R, 329G, 329B, and 329W and the pixel electrode 324 of the color changer 300, and the color change controller 540 are described. Note that the signal wires 329R, 329G, 329B, and 329W are referred to collectively as “signal wires 329.”

As with the signal wire of the color changer 300 of Embodiment 1, the signal wires 329 of the color changer 300 of the present embodiment are provided on the main surface 320a of the first substrate 320 of the color changer 300. The signal wires 329 connect the pixel electrode 324 of each of the pixels 312 and the color change controller 540 to each other via the terminals 328.

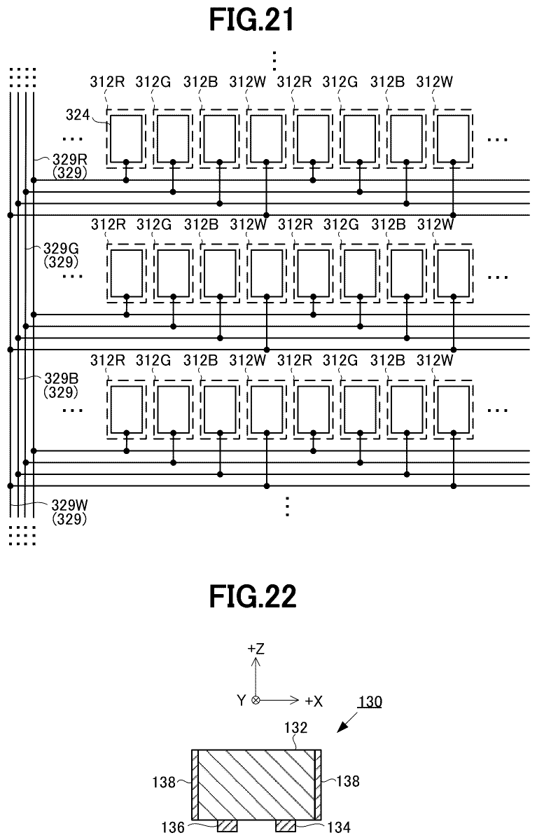

Specifically, as illustrated in FIG. 21, the signal wire 329R connects the pixel electrodes 324 of all of the pixels 312R. The signal wire 329G connects the pixel electrodes 324 of all of the pixels 312G. The signal wire 329B connects the pixel electrodes 324 of all of the pixels 312B. The signal wire 329W connects the pixel electrodes 324 of all of the pixels 312W. The signal wires 329R. 329G, 329B, and 329W are each connected to the color change controller 540 via the terminals 328.

The pixel electrodes 324 of the pixels 312 of the present embodiment are directly connected to the signal wires 329.

The color change controller 540 of the present embodiment supplies, on the basis of commands from outside, gradation voltage (data voltage) via the signal wires 329 to each of the pixels 312R, 312G, 312B, and 312W. Due to this, the color changer 300 of the present embodiment reflects, throughout the entire surface of the emission region 302, illumination light of a uniform color toward the display panel 100 and the decorative member 200.

In the present embodiment, the need to provide the color changer 300 with TFTs is eliminated, and the display device 10 can easily change the color of the design to be presented to the observer with a simple configuration.

### Modified Examples

Embodiments have been described, but various modifications can be made to the present disclosure without departing from the spirit and scope of the present disclosure.

For example, a configuration is possible in which the display panel 100 of Embodiment 1 (micro LED display panel) is driven by TFTs as with the display panel 100 of Embodiment 4.

The display panel 100 is not limited to a display panel that includes light-emitting elements. For example, a configuration is possible in which the display panel 100 is implemented as a liquid crystal display panel including transmission regions in the pixels.

The color changer 300 is not limited to an electrophoresis display panel. A configuration is possible in which the color changer 300 is implemented as a micro LED display panel, an OLED display panel, a liquid crystal display panel, or the like. Additionally, a configuration is possible in which the color changer 300 is implemented as a back light device including an LED element that emits red light, an LED element that emits green light, an LED element that emits blue light, and a light guide plate.

A configuration is possible in which, as illustrated in FIG. 22, the micro LED element 130 of the display panel 100 includes a light blocking film 138 that covers side surfaces of the micro LED chip 132 that emits light. The light blocking film 138 blocks the emission light from the micro LED chip 132. Due to this, color mixing of the display light of the display panel 100 and the light emitted from the color changer 300 can be suppressed, and a design of a desired color can be presented to the observer.

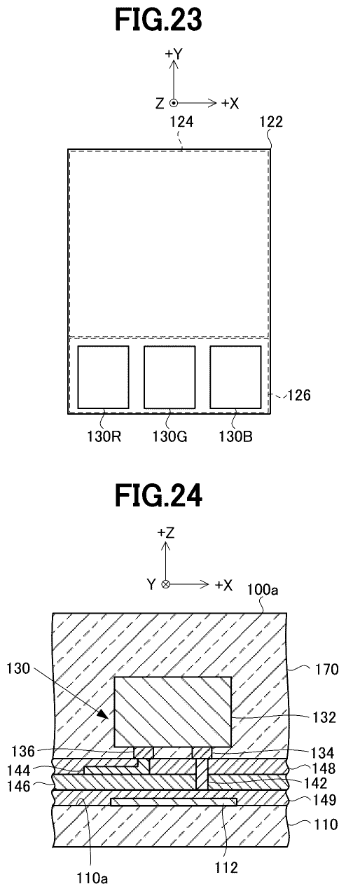

A configuration is possible in which, as illustrated in FIG. 23, the micro LED element 130R that emits red display light, the micro LED element 130G that emits green display light, and the micro LED element 130B that emits blue display light are disposed in the pixel display region 126 of one pixel 122 of the display panel 100. Such a configuration makes it possible to increase the area of the transmission region 124 of each of the pixels 122, and increase the brightness of the color of the design of the decorative member 200.

A configuration is possible in which, as illustrated in FIG. 24, the light-transmitting substrate 110 of the display panel 100 includes a light blocking layer 112 in a region in which the micro LED element 130 is mounted. The light blocking layer 112 blocks the display light from the micro LED element 130 and the light emitted from the color changer 300. Due to this, color mixing of the display light of the display panel 100 and the light emitted from the color changer 300 can be suppressed, and a design of a desired color can be presented to the observer. Note that, in FIG. 24, the light blocking layer 112 is formed on the main surface 110a of the light-transmitting substrate 110 and is covered by a third insulation layer 149.

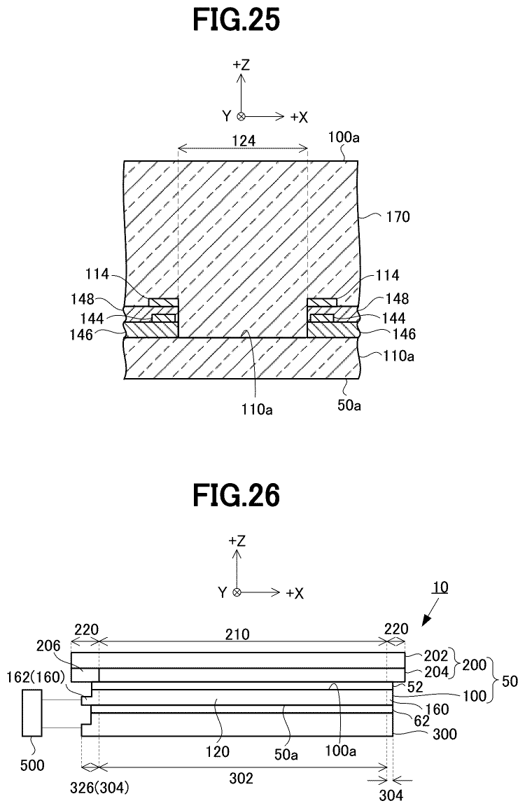

A configuration is possible in which, as illustrated in FIG. 25, the second wiring 144 of the light-transmitting substrate 110 of the display panel 100 is covered by a light blocking layer 114 provided on the observer side (the +Z side). The light blocking layer 114 is provided on the second insulation layer 148 and blocks external light. Due to this configuration, glare that occurs due to reflecting of the second wiring 144 can be suppressed. A configuration is possible in which, as with the second wiring 144, the first wiring 142 of the light-transmitting substrate 110 of the display panel 100 also is covered by a light blocking layer provided on the observer side (the +Z side).

As illustrated in FIG. 1, it is preferable that the terminal region 162 of the display panel 100 and the terminal region 326 of the color changer 300 overlap when viewed planarly. Due to this configuration, it is possible to reduce the size of the terminal regions 162, 326 recognized by the observer.

A configuration is possible in which, as illustrated in FIG. 26, the decorative member 200 includes a light blocker 206 that blocks external light in the region in which the terminal region 162 of the display panel 100 and the terminal region 326 of the color changer 300 overlap. Such a configuration makes it possible to make the boundary between the displayable region 120 and the frame region 160 of the display panel 100 less visible through the decorative member 200. The light blocker 206 is a metallic design that reflects external light, a black design that absorbs external light, or the like.

In Embodiment 5, the color changer 300 emits, toward the display panel 100 and the decorative member 200, illumination light for which the color gradually lightens from the center toward the periphery of the displayable region 120 of the display panel 100. However, a configuration is possible in which the color changer 300 emits, toward the display panel 100 and the decorative member 200, illumination light of different colors for the center of the displayable region 120 and the periphery of the displayable region 120. Due to this configuration, the display device 10 can make it easier for the observer to see the display element.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

1. A display device, comprising:
a display including a display panel in which a plurality of pixels is arranged, and a decorative member disposed on one of a display surface side and a rear surface side of the display panel; and
a color changer that emits illumination light from the rear surface side of the display on the display panel and the decorative member, wherein
each pixel of the plurality of pixels includes a pixel display region that emits display light, and a transmission region that transmits light, and
the color changer emits, in accordance with a color of a design of the decorative member to be presented to an observer, the illumination light of a predetermined color on the display panel and the decorative member.

2. The display device according to claim 1, wherein the decorative member is disposed on the display surface side of the display panel, and transparently displays a display element to be displayed on the display panel.

3. The display device according to claim 2, further comprising:
a controller that controls a color of the display element to be displayed on the display panel, wherein
the controller controls the color of the display element through the decorative member to a complementary color of the color of the design of the decorative member to be presented to the observer.

4. The display device according to claim 2, further comprising:
a controller that controls an amount of the illumination light that the color changer emits on the display panel and the decorative member, wherein
the display panel includes a displayable region in which the plurality of pixels is arranged and in which the display element is displayed, and a frame region surrounding the displayable region,
the decorative member includes, when viewed planarly, a display region that overlaps the displayable region of the display panel and a non-display region that overlaps the frame region of the display panel, and
the controller controls, in accordance with a brightness through the decorative member of the region, of the displayable region of the display panel, not displaying the display element, an amount of the illumination light that the color changer emits on the non-display region of the decorative member.

5. The display device according to claim 2, wherein
each of the display panel and the color changer includes a terminal region in which a terminal that connects to outside is disposed,
the decorative member includes a light blocker that blocks external light, and
when viewed planarly, the terminal region of the display panel, the terminal region of the color changer, and the light blocker of the decorative member overlap.

6. The display device according to claim 1, wherein the display panel includes a light-transmitting substrate in which the plurality of pixels is arranged, and that includes a wiring that drives the plurality of pixels.

7. The display device according to claim 6, wherein each pixel of the plurality of pixels includes a light emitting element in the pixel display region.

8. The display device according to claim 7, wherein the light emitting element is a micro LED element.

9. The display device according to claim 8, wherein the micro LED element includes an LED chip that emits light, an electrode that connects to the wiring, and a light blocking film that covers a side surface of the LED chip.

10. The display device according to claim 8, wherein the light-transmitting substrate includes a light blocking layer in a region in which the micro LED element is mounted.
